(19) United States
(12) Patent Application Publication
(10) Pub. No.: US 2014/0187141 A1
(43) Pub. Date: Jul. 3, 2014

(54) HEAT DISSIPATION APPARATUS FOR EXPANSION BASE

(71) Applicant: HON HAI PRECISION INDUSTRY CO., LTD., New Taipei (TW)

(72) Inventors: CHIH-HANG CHAO, New Taipei (TW); WEI-CHENG CHENG, New Taipei (TW)

(73) Assignee: HON HAI PRECISION INDUSTRY CO., LTD., New Taipei (TW)

(21) Appl. No.: 14/050,539

(22) Filed: Oct. 10, 2013

(30) Foreign Application Priority Data
Dec. 28, 2012 (TW) 101150870

(51) Int. Cl. H05K 7/20

(52) U.S. Cl. CPC H05K 7/20145
USPC 454/251

(57) ABSTRACT

A heat dissipation apparatus includes an expansion base, a fan, an air duct, and a portable device. A number of air inlet slots and an inserting slot are defined in the expansion base. The air duct and the portable device are inserted in the inserting slot. A first air inlet opening and a first air outlet opening are defined in the air duct. An airflow passage is defined between the air inlet slot, the fan, the first air inlet opening, the air duct, the first air outlet opening, and the portable device. The fan is adapted to generate airflow through the portable device in such a manner that airflow flows from the expansion base outside is sucked into and blown out of the portable device via the airflow passage.

### BACKGROUND

1. Technical Field

The present disclosure relates to a heat dissipation apparatus for an expansion base in portable devices.

2. Description of Related Art

Panel computers include expansion bases to receive expansion cards. However, panel computers generate large amount of heat when connected to expansion bases, causing a hazard and a reduction of the life of the panel computers.

Therefore, there is a need for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric, exploded view of an embodiment of a heat dissipation apparatus for an expansion base.

FIG. 2 is an assembled view of the heat dissipation apparatus of FIG. 1.

FIG. 3 is a cross-sectional view of the heat dissipation apparatus of FIG. 2, taken along line III-III.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

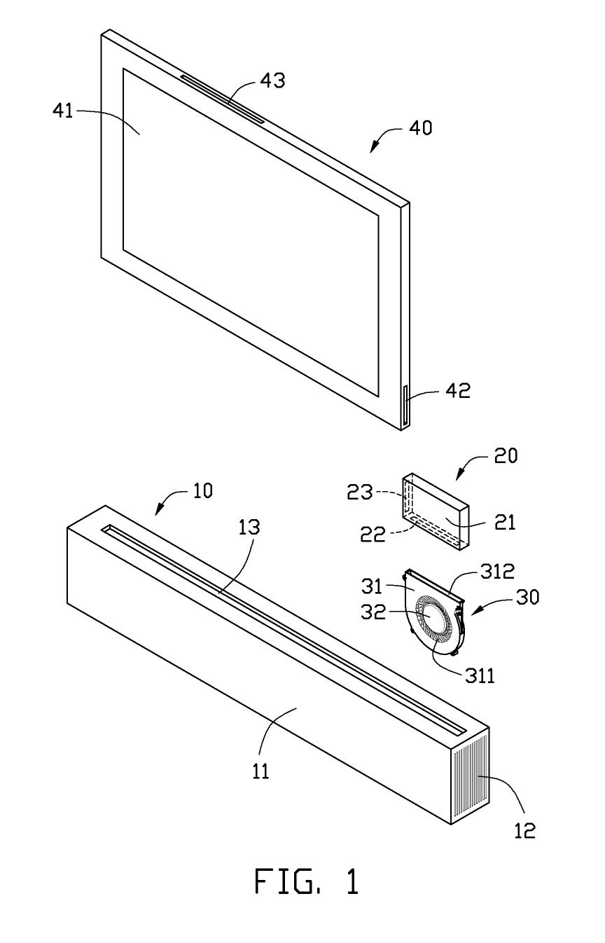

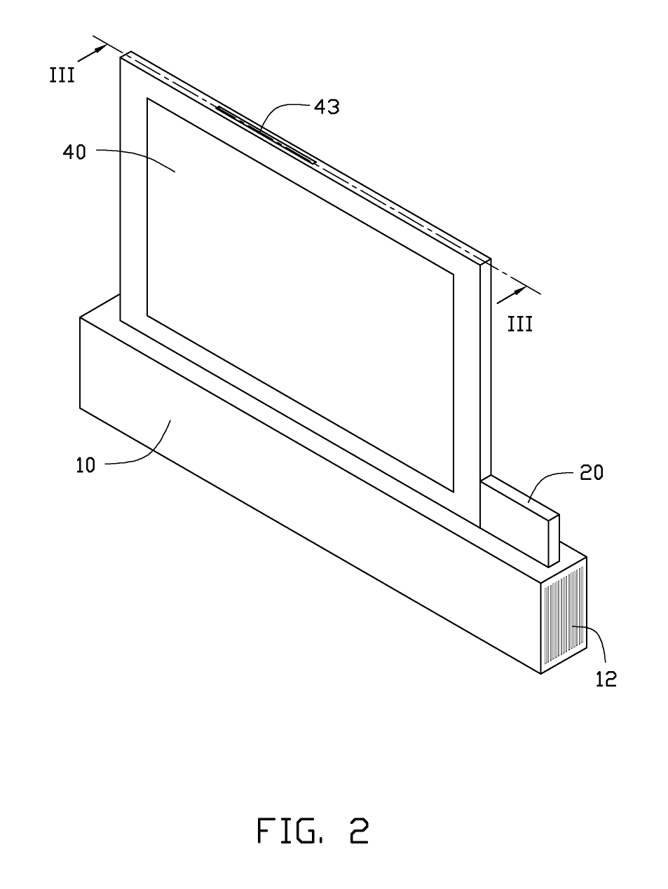

FIGS. 1 and 2 show a heat dissipation apparatus for an expansion base. The heat dissipation apparatus includes an expansion base 10, an air duct 20, a fan 30, and a portable device 40.

The expansion base 10 includes a base body 11. A plurality of air inlet slots 12 is defined in one end of the base body 11. An inserting slot 13 is defined in a top of the base body 11.

The air duct 20 includes a duct body 21. A first air inlet opening 22 is defined in a bottom of the duct body 21. A first air outlet opening 23 is defined in one side of the duct body 21. A first air inlet channel defined by the first air inlet opening 22 is substantially perpendicular to a first air outlet channel defined by the first air outlet opening 23. The first air inlet opening 22 communicates with the first air outlet opening 23. In one embodiment, a length of the inserting slot 13 is greater than a length of the portable device 40, and a width of the inserting slot 13 is substantially equal to a thickness of the portable device 40.

The fan 30 includes a shell 31 and a rotatable fan blade module 32. A second air inlet opening 311 is defined in one side of the shell 31. The shell 31 further has a second air outlet opening 312 defined in a top of the shell 31. The second air inlet opening 311 allows air to flow into the fan 30 along a direction substantially in line with a rotating axle of the fan blade module 32. The second air outlet opening 312 allows air to flow out of the fan 30 along a direction substantially perpendicular to the rotating axle of the fan blade module 32. In one embodiment, a dimension of the second air outlet opening 312 is equal to a dimension of the first air inlet opening 22.

The portable device 40 includes a main body 41. A third air inlet opening 42 is defined in one side of the main body 41. A third air outlet opening 43 is defined in a top of the main body 41. A second air inlet channel defined by the third air inlet opening 42 is substantially perpendicular to a second air outlet channel defined by the third air outlet opening 43. The third air inlet opening 42 communicates with the third air outlet opening 43.

In assembly, the fan 30 is fixed in the expansion base 10, such that the second air outlet opening 312 of the fan 30 faces out of the inserting slot 13. The air duct 20 is received in the inserting slot 13, such that the first air inlet opening 22 of the air duct 20 is aligned with the second air outlet opening 312 of the fan 30. The portable device 40 is received in the inserting slot 13, such that the third air inlet opening 42 of the portable device 40 is aligned with the first air outlet opening 23 of the air duct 20.

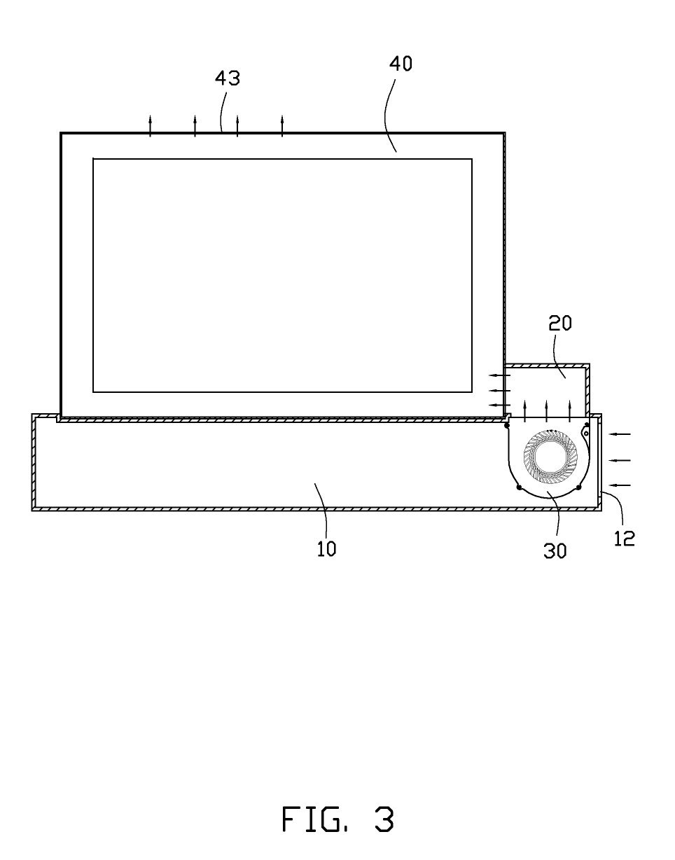

FIG. 3 shows that in operation, the portable device 40 generates large amounts of heat when powered on. Air outside the expansion base 10 is sucked into the fan 30 via the plurality of air inlet slots 12 and the second air inlet opening 311. The air is blown out of the fan 30 through the second air outlet opening 312 toward the first air inlet opening 22 of the air duct 20. The air passes through the air duct 20 and is blown out of the air duct 20 through the first air outlet opening 23. The air is then blown toward the third air inlet opening 42 of the portable device 40 to remove the heat accumulated in the portable device 40. The heated air is then blown out of the portable device 40 via the third air outlet opening 43. Therefore, the heat dissipation efficiency of the heat dissipation apparatus is significantly improved.

Using a software application called ICEPAK to simulate the efficiency of the heat dissipation apparatus, the following results of an embodiment shown below were obtained. For the simulated conditions, a power dissipation of a CPU of the portable device 40 was 1.16 watts (W), a power dissipation of a memory of the portable device 40 was 0.29 W, a power dissipation of a power control unit of the portable device 40 was 0.86 W, the fan 30 had a dimension of 92 millimeters (mm)×92 mm×25 mm (length×width×height), a maximum air flow rate of the fan 30 was 35.32 cubic feet per minute (cfm), a rated speed of the fan 30 was 2000 revolutions per minute (rpm), and a maximum static pressure of the fan 30 was 0.084 inch-H₂O.

The simulation according to the simulated conditions show that when using the disclosed heat dissipation apparatus, the maximum temperature of the CPU and the memory is 62.6 degrees Celsius, and the maximum temperature of the power control unit is 64.7 degrees Celsius. In contrast, when using any other heat dissipation apparatus, the maximum temperature of the CPU and the memory is 70.2 degrees Celsius, and the maximum temperature of the power control unit is 71.1 degrees Celsius. Therefore, the maximum temperature of the portable device 40 is significantly decreased, and heat dissipation efficiency is improved.

Even though numerous characteristics and advantages of the present disclosure have been set forth in the foregoing description, together with details of the structure and function of the disclosure, the disclosure is illustrative only, and changes may be made in detail, especially in the matters of shape, size, and the arrangement of parts within the principles of the disclosure to the full extent indicated by the broad general meaning of the terms in which the appended claims are expressed.

What is claimed is:

1. A heat dissipation apparatus, comprising:
an expansion base comprising a base body, an air inlet slot defined at one side of the base body, an inserting slot defined at a top of the base body;
a fan fixed in the expansion base;
an air duct inserted in the inserting slot; the air duct comprises a duct body, a first air inlet opening defined at a bottom of the duct body, a first air outlet opening defined at one side of the duct body, a first air inlet channel defined by the first air inlet opening, a first air outlet channel defined by the first air outlet opening, the first air inlet channel being substantially perpendicularly to the first air outlet channel; and
a portable device inserted in the inserting slot; wherein an airflow passage is defined between the air inlet slot, the fan, the first air inlet opening, the air duct, the first air outlet opening, and the portable device; the fan is adapted to generate airflow through the portable device so that airflow flows from the expansion base outside is sucked into and blown out of the portable device via the airflow passage

2. The heat dissipation apparatus of claim 1, wherein the fan comprises a shell and a rotatable fan blade module; a second air inlet opening is defined at one side of the shell; and a second air outlet opening is defined at a top plate of the shell.

3. The heat dissipation apparatus of claim 2, wherein the second air inlet opening allows air to flow into the fan in a direction which is in line with a rotating axle of the fan blade module.

4. The heat dissipation apparatus of claim 3, wherein the second air outlet opening allows air to flow out of the fan in a direction which is substantially perpendicularly to the rotating axle of the fan blade module.

5. The heat dissipation apparatus of claim 4, wherein a dimension of the second air outlet opening is equal to a dimension of the first air inlet opening.

6. The heat dissipation apparatus of claim 5, wherein the portable device comprises a main body; a third air inlet opening is defined at one side of the main body; and a third air outlet opening is defined at a top of the main body.

7. The heat dissipation apparatus of claim 6, wherein the portable device further comprises a second air inlet channel defined by the third air inlet opening and a second air outlet channel defined by the third air outlet opening, the second air inlet channel being substantially perpendicularly to the second air outlet channel.

8. The heat dissipation apparatus of claim 6, wherein the first air inlet opening is communicated with the first air outlet opening; and the third air inlet opening is communicated with the third air outlet opening.

9. The heat dissipation apparatus of claim 8, wherein a length of the inserting slot is greater than a length of the portable device; and a thickness of the inserting slot is equal to a thickness of the portable device.

10. A heat dissipation apparatus, comprising:
an expansion base defining an air inlet slot at one side of the expansion base and an inserting slot at a top expansion base;
a fan fixed in the expansion base, a second air inlet opening and a second air outlet opening being defined in the fan;
an air duct inserted in the inserting slot; the air duct comprises a first air inlet opening at a bottom of the air duct and a first air outlet opening at one side of the air duct; and
a portable device inserted in the inserting slot; wherein an airflow passage is defined between the air inlet slot, the second air inlet opening, the second air outlet opening, the fan, the first air inlet opening, the air duct, the first air outlet opening, and the portable device; the fan is adapted to generate airflow through the portable device so that airflow flows from the expansion base outside is sucked into and blown out of the portable device via the airflow passage.

11. The heat dissipation apparatus of claim 10, wherein the fan comprises a shell and a rotatable fan blade module; the second air inlet opening is defined at one side of the shell; and the second air outlet opening is defined at a top plate of the shell.

12. The heat dissipation apparatus of claim 11, wherein the second air inlet opening allows air to flow into the fan in a direction which is in line with a rotating axle of the fan blade module.

13. The heat dissipation apparatus of claim 12, wherein the second air outlet opening allows air to flow out of the fan in a direction which is substantially perpendicularly to the rotating axle of the fan blade module.

14. The heat dissipation apparatus of claim 13, wherein a dimension of the second air outlet opening is equal to a dimension of the first air inlet opening.

15. The heat dissipation apparatus of claim 14, wherein the portable device comprises a main body; a third air inlet opening is defined at one side of the main body; and a third air outlet opening is defined at a top of the main body.

16. The heat dissipation apparatus of claim 15, wherein the air duct further comprises a first air inlet channel defined by the first air inlet opening and a first air outlet channel defined by the first air outlet opening, the first air inlet channel being substantially perpendicularly to the first air outlet channel; the portable device further comprises a second air inlet channel defined by the third air inlet opening and a second air outlet channel defined by the third air outlet opening, the second air inlet channel being substantially perpendicularly to the second air outlet channel.

17. The heat dissipation apparatus of claim 15, wherein the first air inlet opening is communicated with the first air outlet opening; and the third air inlet opening is communicated with the third air outlet opening.

18. The heat dissipation apparatus of claim 17, wherein a length of the inserting slot is greater than a length of the portable device; and a thickness of the inserting slot is equal to a thickness of the portable device.
